(19) United States
(12) Patent Application Publication
(10) Pub. No.: US 2015/0091775 A1
(43) Pub. Date: Apr. 2, 2015

(54) DIPLEXER AND METHOD FOR MANUFACTURING THE SAME

(71) Applicant: SAMSUNG ELECTRO-MECHANICS CO., LTD., Suwon-Si (KR)

(72) Inventors: Seung Goo JANG, Suwon-Si (KR); Sun Hong KIM, Suwon-Si (KR); Hyun Jun LEE, Suwon-Si (KR)

(73) Assignee: SAMSUNG ELECTRO-MECHANICS CO., LTD., Suwon-Si (KR)

(21) Appl. No.: 14/267,550

(22) Filed: May 1, 2014

(30) Foreign Application Priority Data
Sep. 27, 2013 (KR) 10-2013-0115636

(51) Int. Cl. H03H 7/46; H01Q 1/48

(52) U.S. Cl. CPC H03H 7/468; H01Q 1/48
USPC 343/846; 333/132; 29/602.1

(57) ABSTRACT

A diplexer may include a diplexer circuit unit including a first branch operating in a first frequency band and a second branch operating in a second frequency band, a static-electricity protection circuit unit connected to at least one of the first branch and the second branch in parallel so as to discharge static electricity flowing in the first or second branch toward an avoidance path, and a compensation circuit unit connected to at least one of the first branch and second branch so as to compensate for degradation caused by the static-electricity protection circuit unit.

### CROSS-REFERENCE TO RELATED APPLICATION

This application claims the benefit of Korean Patent Application No. 10-2013-0115636 filed on Sep. 27, 2013, with the Korean Intellectual Property Office, the disclosure of which is incorporated herein by reference.

### BACKGROUND

The present disclosure relates to a diplexer and a method for manufacturing the same.

As wireless communications technology and the infrastructure thereof has developed, wireless communications devices have been employed in various electronic devices.

In particular, as single devices are increasingly required to be operable within different communications schemes, a diplexer that can be used in multiple frequency bands is widely employed in various applications.

For diplexers used in various applications, various requirements have been made, associated with diplexer usage environments. Thereamong, good electrostatic discharge (ESD) characteristics have emerged as an important issue.

In the related art, although schemes for preventing static electricity in wireless communications devices exist, no scheme for preventing static electricity or for improving characteristics associated therewith in diplexers themselves have existed. Therefore, device performance may be deteriorated due to static electricity.

Patent Document 1 relates to a diplexer circuit for a dual band communications device, and Patent Document 2 relates to a duplexer circuit. However, the patent documents fail to teach a solution to address the above-mentioned problem.

### RELATED ART DOCUMENT

### (Patent Document 1) Korean Patent Laid-Open Publication No. 2002-0060344

### (Patent Document 2) Korean Patent Laid-Open Publication No. 2005-0023642

### SUMMARY

An aspect of the present disclosure may provide a diplexer and a method for manufacturing the same, capable of providing protection against static electricity and ensuring performance thereof, by way of adding a static-electricity protection circuit for preventing static electricity in a diplexer circuit and compensating for the possibly of degradation due to the added static electricity protection circuit.

According to an aspect of the present disclosure, a diplexer may include: a diplexer circuit unit including a first branch operating in a first frequency band and a second branch operating in a second frequency band; a static-electricity protection circuit unit connected to at least one of the first branch and the second branch in parallel so as to discharge static electricity flowing in the first or second branch toward an avoidance path; and a compensation circuit unit connected to at least one of the first branch and second branch so as to compensate for degradation caused by the static-electricity protection circuit unit.

The diplexer circuit unit may include an antenna connected to the first branch and the second branch in series, and the static-electricity protection circuit unit may discharge the static electricity introduced by the antenna into ground.

The compensation circuit unit may be connected to at least one of the first branch and the second branch in a location in which the static-electricity protection circuit unit is connected in parallel.

The compensation circuit unit may configure a parallel resonance circuit with the static-electricity protection circuit unit so as to perform filtering.

The static-electricity protection unit may include at least one inductor that has one terminal thereof connected to at least one of the first branch and the second branch and the other terminal thereof grounded.

The compensation circuit unit may include at least one capacitor that has one terminal thereof connected to at least one of the first branch and the second branch in a location in which the static-electricity protection circuit unit is connected, and the other terminal thereof grounded.

The inductor of the static-electricity protection circuit unit may configure a LC filter with the capacitor of the compensation circuit.

The compensation circuit unit may include: a first capacitor that has one terminal thereof connected to at least one of the first and second branches in a location in which the static-electricity protection circuit unit is connected and the other terminal thereof grounded; and a second capacitor connected to at least one of the first and second branches in a location in which the static-electricity protection circuit unit is connected in series.

According to another aspect of the present disclosure, a method for manufacturing a diplexer may include: configuring a diplexer circuit including a first branch operating in a first frequency band and a second branch operating in a second frequency band; connecting at least one inductor to at least one of the first and second branches in parallel; and connecting at least one capacitor to the branch in a location in which the at least one inductor is connected in series or in parallel.

The connecting of the at least one inductor may include: adding a first inductor that has one terminal thereof connected to the first branch and the other terminal thereof grounded; and adding a second inductor that has one terminal thereof connected to the second branch and the other terminal thereof grounded.

The connecting of the at least one capacitor may include: adding a first capacitor connected to the first branch in parallel, wherein the first inductor and the first capacitor configure a parallel resonance circuit.

The first inductor and the first capacitor may act as a band pass filter for the first frequency band.

The connecting of the at least one capacitor may further include: adding a second capacitor connected to an output terminal of the first branch in parallel, wherein the second capacitor matches a load of the first inductor.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a circuit diagram of a typical diplexer circuit;

FIG. 2 is a circuit diagram for illustrating a diplexer circuit capable of preventing static electricity according to an exemplary embodiment of the present disclosure;

FIG. 3 is a circuit diagram for illustrating a diplexer circuit capable of preventing static electricity according to another exemplary embodiment of the present disclosure;

FIG. 4 is a circuit diagram for illustrating a diplexer circuit capable of preventing static electricity according to another exemplary embodiment of the present disclosure; and

FIG. 5 is a flowchart for illustrating a method for manufacturing a diplexer according to an exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. Throughout the drawings, the same or like reference numerals will be used to designate the same or like elements.

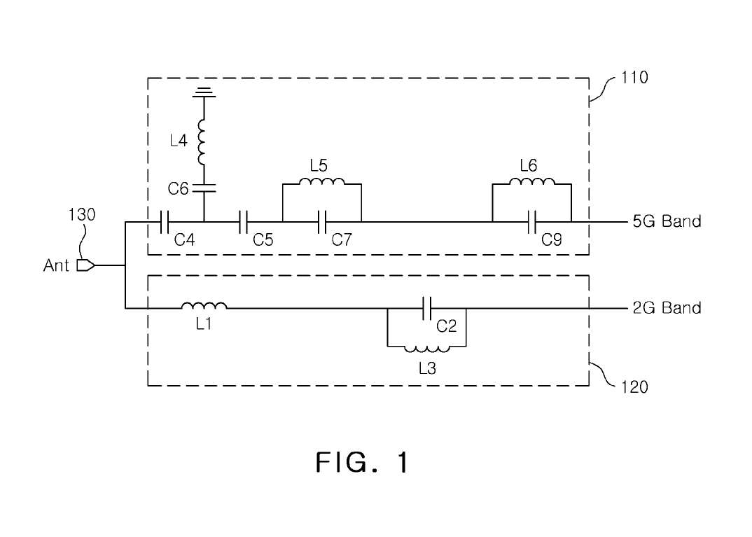

FIG. 1 is a circuit diagram of a typical diplexer circuit.

The diplexer circuit shown in FIG. 1 does not include a circuit to prevent static electricity.

The diplexer circuit shown in FIG. 1 may include an antenna 130, a first branch 110, and a second branch 120.

The first branch 110 may act when a signal received by the antenna 130 falls in a first frequency band, and the second branch 120 may act when the signal received by the antenna 130 falls in a second frequency band. In the shown circuit, the first frequency band is 5 GHz and the second frequency band is 2 GHz.

In this example, capacitors C4, C5 and C6 and an inductor L4 on the first branch 110 act as an attenuation circuit against the 2 GHz frequency band while an inductor L5 and a capacitor C7, or an inductor L6 and a capacitor C9 act as a circuit to attenuate second harmonics in the 5 GHz frequency band.

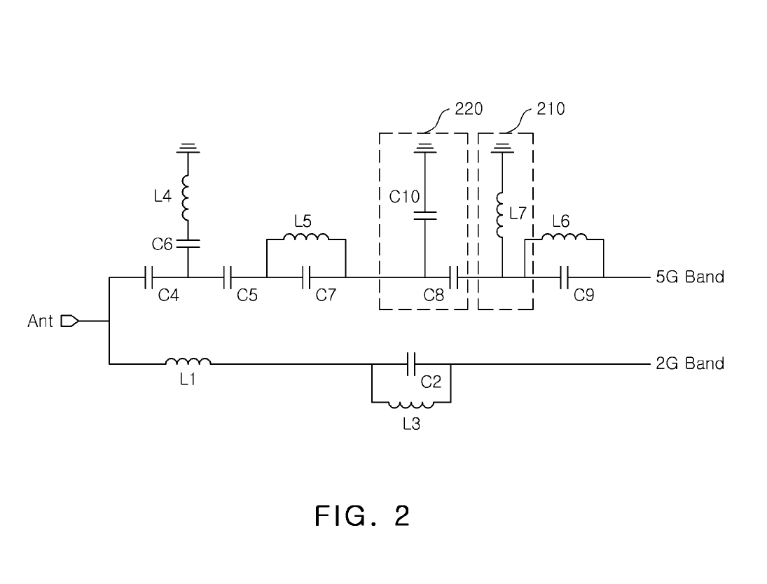

The configuration of the diplexer circuit shown in FIG. 1 and the configurations of the diplexer circuits shown in FIGS. 2 through 4 are merely illustrative and may be changed in design depending on actual implementation. Accordingly, it is apparent that the scope sought to be protected by the present disclosure is not defined by the examples of the diplexer circuits shown in FIGS. 2 through 4.

Hereinafter, diplexer circuits according to various exemplary embodiments of the present disclosure will be described with reference to FIGS. 2 through 4.

FIG. 2 is a circuit diagram for illustrating a diplexer circuit capable of preventing static electricity according to an exemplary embodiment of the present disclosure.

In FIG. 2, the diplexer may include a diplexer circuit unit, a static-electricity protection circuit unit, and a compensation circuit unit.

Similarly to FIG. 1, the diplexer circuit unit may include a first branch operating in a first frequency band and a second branch operating in a second frequency band. The diplexer circuit unit may include an antenna connected to the first and second branches in series.

The static-electricity protection unit 210 may be connected to at least one of the first and second branches in parallel so as to discharge static electricity flowing in the first or second branch toward an avoidance path. For example, the static-electricity protection circuit unit 210 may discharge the static electricity introduced via the antenna into ground. In the example shown in FIG. 2, the static-electricity protection circuit unit 210 is disposed on the branch of the 5 GHz frequency band.

In an exemplary embodiment, the static-electricity protection unit 210 may include at least one inductor that has one terminal connected to at least one of the first branch and the second branch and the other terminal grounded. In FIG. 2, an inductor L7 configures the static-electricity protection circuit unit 210, with one terminal thereof connected to the branch of the 5 GHz frequency band and the other terminal thereof grounded.

The compensation circuit unit 220 may be connected to at least one of the first branch and the second branch so as to compensate for degradation caused by the static-electricity protection circuit unit 210. As can be seen from FIG. 2, the compensation circuit unit 220 is disposed on the branch of the GHz frequency band in a location in which the static-electricity protection circuit unit 210 is disposed.

The compensation circuit unit 220 may be connected to at least one of the first branch and the second branch in a location in which the static-electricity protection circuit unit 210 is connected in parallel.

The compensation circuit unit 220 may consist of capacitors C8 and C10. The capacitor C8 may be connected to the branch of 5 GHz frequency band to which the static-electricity protection circuit unit 210 is connected in series. The capacitor C10 may have one terminal thereof connected to the branch of 5 GHz frequency band and the other terminal thereof grounded.

That is, when the inductor L7 of the static-electricity protection circuit unit 210 is added to the branch of 5 GHz frequency band, an error may occur in the function of resonant units for removing harmonics L5 and C7, and L6 and C9. In order to compensate for the error, the compensation circuit unit 220 that includes the capacitors C8 and C10 may be added.

The capacitor C10 may configure a parallel resonance circuit with the inductor L7 so as to compensate for performance deterioration cause by insertion loss, while the capacitor C8 may compensate for the coupling of the resonance units for removing harmonics L5 and C7, and L6 and C9 so as to remove harmonics normally.

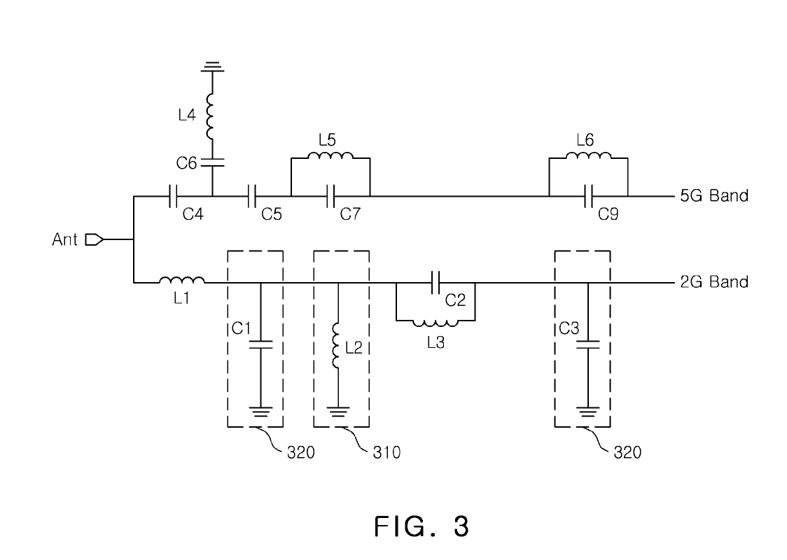

FIG. 3 is a circuit diagram for illustrating a diplexer circuit capable of preventing static electricity according to another exemplary embodiment of the present disclosure.

In the example shown in FIG. 3, a static-electricity protection circuit unit 310 and compensation circuit units 320 and 330 are disposed on the branch of 2 GHZ frequency band.

The static-electricity protection circuit unit 310 may remove static-electricity introduced into the branch of 2 GHz frequency band, and the compensation circuit units 320 and 330 may compensate for degradation caused by the static-electricity protection circuit unit 310.

The static-electricity protection circuit unit 310 may consist of an inductor L2 connected to the branch of 2 GHz frequency band in parallel, and the compensation circuit unit 320 and 330 may consist of capacitors C1 and C3, respectively, connected to the branch of 2 GHz frequency band in parallel. One terminal of each of the inductor L2, the capacitors C1 and C3 is connected to the branch of 2 GHz frequency band while the other terminal thereof is grounded.

When the inductor L2 of the static-electricity protection circuit unit 310 is connected to the branch of 2 GH frequency band, loss in a lower frequency band of 2 GHz frequency band may be increased. Accordingly, in order to compensate for this, a capacitor C1 may be added. The added capacitor C1 and the inductor L2 may configure a parallel resonance circuit so as to act as a band pass filter for the pass frequency of the 2 GHz frequency band.

In addition, when the inductor L2 is connected to the branch of the 2 GHz frequency band, an output from the branch of the 2 GHz frequency band may deviate from a constant match value (e.g., 50 ohm). Accordingly, the capacitor C3 is added so that the output from the branch of the 2 GHz frequency band has a constant matching value (e.g., 50 ohm).

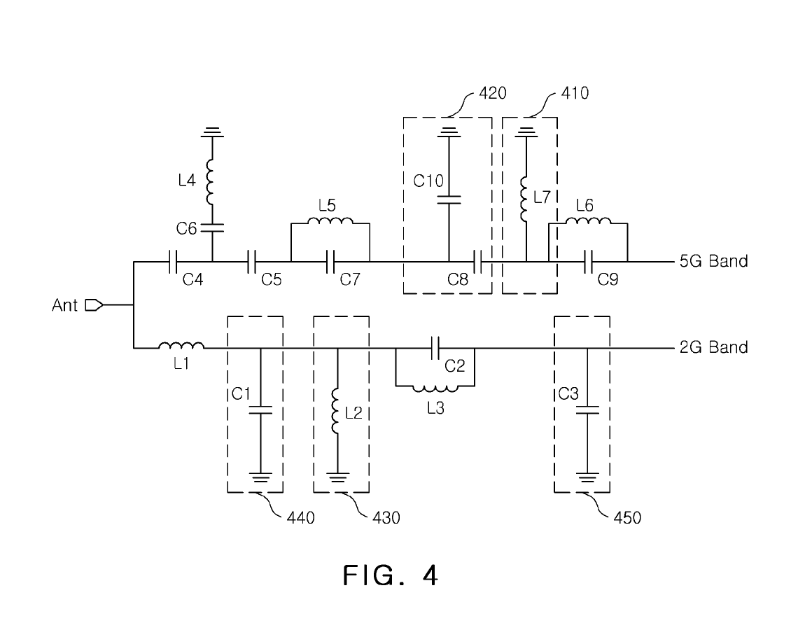

FIG. 4 is a circuit diagram for illustrating a diplexer circuit capable of preventing static electricity according to another exemplary embodiment of the present disclosure.

In FIG. 4, the static-electricity protection circuit units 410 and 430 and the compensation circuit units 420, 440 and 450 illustrated in FIGS. 2 and 3 are combined.

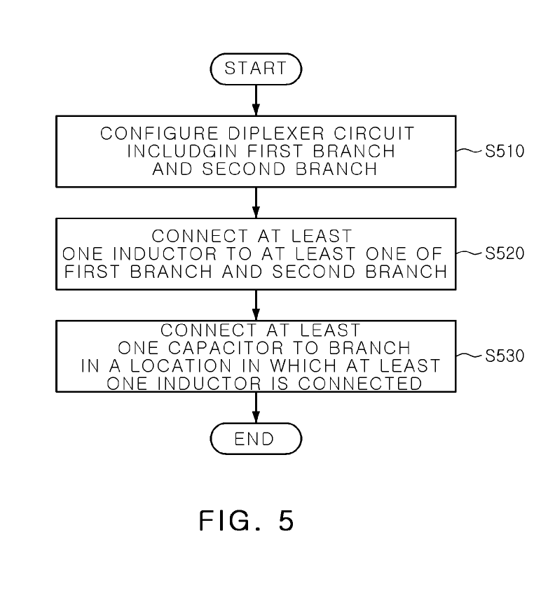

FIG. 5 is a flowchart for illustrating a method for manufacturing a diplexer according to an exemplary embodiment of the present disclosure.

The method for manufacturing a diplexer according to the exemplary embodiment illustrated in FIG. 5 is to manufacture the diplexers described above with respect to FIGS. 2 through 4, and, therefore, a redundant description on the like elements described above with respect to FIGS. 2 through 4 will be omitted.

Referring to FIG. 5, the method for manufacturing a diplexer may include configuring a diplexer circuit that includes a first branch operating in a first frequency band and a second branch operating in a second frequency band (S510).

Then, at least one inductor may be connected to at least one of the first and second branches in parallel, to thereby configure a static-electricity protection circuit (S520).

In addition, at least one capacitor may be connected to the branch in a location in which the at least one inductor is connected in series or in parallel, to thereby configure a compensation circuit (S530).

In an exemplary embodiment, operation 5520 may include adding to the first branch a first inductor having one terminal thereof connected to the first branch and the other terminal thereof grounded, and adding to the second branch a second inductor having one terminal connected to the second branch and the other terminal thereof grounded.

In an exemplary embodiment, operation 5530 may include adding a first capacitor connected to the first branch in parallel. Here, the first inductor and the first capacitor may configure a parallel resonance circuit.

In exemplary embodiment, the first inductor and the first capacitor may act as a band pass filter for the first frequency band.

In an exemplary embodiment, operation 5530 may further include adding a second capacitor connected to the output terminal of the first branch in parallel. Here, the second capacitor may match the load of the first inductor.

As set forth above, according to exemplary embodiments of the present disclosure, static electricity protection can be provided by itself and the performance of a diplexer can be ensured, by way of adding a static-electricity protection circuit for preventing static electricity in a diplexer circuit and compensating for degradation possibly caused by the added static electricity protection circuit.

While exemplary embodiments have been shown and described above, it will be apparent to those skilled in the art that modifications and variations could be made without departing from the spirit and scope of the present disclosure as defined by the appended claims.

What is claimed is:

1. A diplexer, comprising:
a diplexer circuit unit including a first branch operating in a first frequency band and a second branch operating in a second frequency band;
a static-electricity protection circuit unit connected to at least one of the first branch and the second branch in parallel so as to discharge static electricity flowing in the first or second branch toward an avoidance path; and
a compensation circuit unit connected to at least one of the first branch and second branch so as to compensate for degradation caused by the static-electricity protection circuit unit.

2. The diplexer of claim 1, wherein the diplexer circuit unit includes an antenna connected to the first branch and the second branch in series, and
the static-electricity protection circuit unit discharges the static electricity introduced by the antenna into ground.

3. The diplexer of claim 1, wherein the compensation circuit unit is connected to at least one of the first and second branches in a location in which the static-electricity protection circuit unit is connected in parallel.

4. The diplexer of claim 1, wherein the compensation circuit unit configures a parallel resonance circuit with the static-electricity protection circuit unit so as to perform filtering.

5. The diplexer of claim 1, wherein the static-electricity protection unit includes at least one inductor that has one terminal thereof connected to at least one of the first branch and the second branch and the other terminal thereof grounded.

6. The diplexer of claim 5, wherein the compensation circuit unit includes at least one capacitor that has one terminal thereof connected to at least one of the first branch and the second branch in a location in which the static-electricity protection circuit unit is connected, and the other terminal thereof grounded.

7. The diplexer of claim 6, wherein the inductor of the static-electricity protection circuit unit configures a LC filter with the capacitor of the compensation circuit.

8. The diplexer of claim 5, wherein the compensation circuit unit includes:
a first capacitor that has one terminal thereof connected to at least one of the first and second branches in a location in which the static-electricity protection circuit unit is connected and the other terminal thereof grounded; and
a second capacitor connected to at least one of the first and second branches in a location in which the static-electricity protection circuit unit is connected in series.

9. A method for manufacturing a diplexer, comprising:
configuring a diplexer circuit including a first branch operating in a first frequency band and a second branch operating in a second frequency band;
connecting at least one inductor to at least one of the first and second branches in parallel; and
connecting at least one capacitor to the branch in a location in which the at least one inductor is connected in series or in parallel.

10. The method of claim 9, wherein the connecting of the at least one inductor includes:
adding a first inductor that has one terminal thereof connected to the first branch and the other terminal thereof grounded; and
adding a second inductor that has one terminal thereof connected to the second branch and the other terminal thereof grounded.

11. The method of claim 10, wherein the connecting of the at least one capacitor includes adding a first capacitor connected to the first branch in parallel,
wherein the first inductor and the first capacitor configure a parallel resonance circuit.

12. The method of claim 11, wherein the first inductor and the first capacitor act as a band pass filter for the first frequency band.

13. The method of claim 11, wherein the connecting of the at least one capacitor further includes: adding a second capacitor connected to an output terminal of the first branch in parallel,
wherein the second capacitor matches a load of the first inductor.
